(19) United States
(12) Patent Application Publication
(10) Pub. No.: US 2019/0235033 A1
(43) Pub. Date: Aug. 1, 2019

(54) Simulation Device, Recording Medium, and Simulation Method

(71) Applicant: Kyoto University, Kyoto-shi, Kyoto (JP)

(72) Inventor: Masayuki Ohzeki, Kyoto-shi, Kyoto (JP)

(21) Appl. No.: 16/341,024

(22) PCT Filed: Jun. 26, 2017
(86) PCT No.: PCT/JP2017/023378

§ 371 Date: Apr. 10, 2019

(30) Foreign Application Priority Data
Oct. 20, 2016 (JP) 2016-206265

(51) Int. Cl. G01R 33/12; H03K 19/195; G06N 7/00; G06N 10/00; G06F 17/13; G06F 17/50

(52) U.S. Cl. CPC G01R 33/1284; H03K 19/195; G06F 17/5009; G06N 10/00; G06F 17/13; G06N 7/005

(57) ABSTRACT

A simulation device includes a magnetization computation unit for computing the average of the sum of predetermined direction components of a plurality of spins as magnetization of the predetermined direction, an initial Hamiltonian computation unit for computing a magnetic field function, which includes a first order term and a second or higher order term of magnetization, as the initial Hamiltonian, a first probability distribution function computation unit for computing a probability distribution function for the initial Hamiltonian including a term of multiplication of the magnetic field function and a delta function including a variable of a difference between the magnetization and the average of the sum of predetermined direction components of the spins; a spin variable update unit for updating a spin variable, a determination unit for determining whether the system has been put into an equilibrium state or not, a first magnetization calculation unit for calculating magnetization of the predetermined direction of the system in the equilibrium state, a magnetic field calculation unit for calculating a magnetic field of the predetermined direction, a magnetic field determination unit for determining whether the magnetic field is in a steady state or not, and a physical quantity calculation unit for calculating a physical quantity related to the system are provided.

### CROSS-REFERENCE TO RELATED APPLICATIONS

This application is the national phase under 35 U.S.C. § 371 of PCT International Application No. PCT/JP2017/023378 which has an International filing date of Jun. 26, 2017 and designated the United States of America.

### FIELD

The present invention relates to a simulation device, a recording medium, and a simulation method.

### BACKGROUND

A problem of minimizing a discrete multivariable single-valued function (cost function) is called as an optimization problem. Many important subjects including pattern recognition, natural language processing, artificial intelligence, and machine learning that require large-scale calculation can be formulated as an optimization problem. Moreover, quantum annealing is attracting attention in recent years as an algorithm for solving an optimization problem by making good use of quantum-mechanical property such as quantum fluctuation.

In quantum annealing, a cost function is represented as an Ising model, which is a function of a binary variable, and is formulated as a problem of finding the minimum value of the function. Quantum annealing is described in Literature “Yuya Seki, Hidetoshi Nishimori, “Quantum annealing with antiferromagnetic fluctuations”, Phys. Rev. E 85, 051112(2012)”, for example.

In quantum annealing, a transverse field of the x direction is to utilized as quantum-mechanical fluctuation, in which a spin oriented in the z direction (a number of spins expressed by a bold letter σ in vector notation) is inverted, as expressed in Expression (1). The effect of such quantum fluctuation enables searching of a further optimal solution.

$$H ( t ) = {H}_{0} ( σ ) - Γ ( t ) {\sum }_{i = 1}^{N} {σ}_{i}^{x} \qquad ( 1 )$$

Here, a Hamiltonian H0 denotes a cost function of an optimization problem, and H0 is selected in a manner such that the ground state of the Hamiltonian H0 becomes the optimal solution. Symbol σ is a spin variable, sigma of x-direction components of spins is an initial Hamiltonian expressing a transverse field, and coefficient Γ is a parameter for controlling the intensity of quantum fluctuation. Coefficient Γ is set to an extremely large value in the initial state (time t=0), is decreased with the lapse of time, and eventually becomes 0. First, superposition of a number of states is realized by large quantum fluctuation, and the state is investigated. As Γ gradually decreases while continuously tracing a momentary grand state at each time point, the relative weight of the Hamiltonian H0 becomes larger than the initial Hamiltonian, and the state eventually reaches the grand state of the Hamiltonian H0. This means that a solution for the optimization problem has been obtained, and a required physical quantity has been calculated.

FIG. 15 is a schematic view illustrating an example of an energy gap of a quantum system. In FIG. 15, the horizontal axis represents time, while the vertical axis represents energy. When following the energy level of the quantum system in time series, the energy level of the ground state and the energy level of an excited state sometimes come close to each other. The symbol Δ denotes an energy gap between the ground state and the first excited state. Symbol T denotes time required for quantum annealing, i.e., calculation time taken until an optimal solution is found. Symbol N denotes the number of spins. For the energy gap Δ illustrated in FIG. 15, quantum phase transition (first-order phase transition) occurs, and the calculation time T increases exponentially and becomes an extremely large value. Therefore, quantum annealing sometimes requires extremely long calculation time. Even a normal computer has a problem that extremely long time is required for solving an optimization problem, and calculation time similarly becomes long when applying quantum annealing to such a problem. Behind this, quantum phase transition exists.

The Literature “Yuya Seki, Hidetoshi Nishimori, “Quantum annealing with antiferromagnetic fluctuations”, Phys. Rev. E 85, 051112(2012)” describes a method of avoiding the above-described first-order phase transition.

That is, a term of the square of the sum of x-direction components of spins (also referred to as antiferromagnetic XX interaction) is added as expressed in Expression (2). Gamma γ in Expression (2) is a coefficient.

$$H ( t ) = {H}_{0} ( σ ) - Γ ( t ) {\sum }_{i = 1}^{N} {σ}_{i}^{x} + \frac{N γ}{2} {( \frac{1}{N} {\sum }_{i = 1}^{N} {σ}_{i}^{x} )}^{2} \qquad ( 2 )$$

FIG. 16 is a schematic view illustrating an example of a phase diagram. In FIG. 16, the horizontal axis represents coefficient gamma γ, and the vertical axis represents the inverse number of the coefficient Γ. Symbol QP denotes a quantum paramagnetic phase, and symbol F denotes a ferromagnetic phase. The broken line represents the boundary between QP and F. Moreover, the solid line in the horizontal direction represents the line of first-order phase transition. In the case of a Hamiltonian expressed in Expression (1), a problem of first-order phase transition is encountered when changing coefficient Γ from an extremely large value to a small value as represented by the broken line denoted by symbol A. In the case of a Hamiltonian expressed in Expression (2), it is possible to avoid first-order phase transition as represented by the solid line denoted by symbol B.

### SUMMARY

However, the antiferromagnetic XX interaction in Expression (2) has a term of the square of the sum of x-direction components of spins, and the effect by the x-direction components of spins is an effect peculiar to quantum mechanics and is basically expressed by a complex number. In a case where XX interaction is utilized, this sometimes result in the square of a complex number, i.e., a negative value, a so-called minus sign problem in which Boltzmann weight required for carrying out stochastic sampling becomes minus occurs, and therefore it has been considered that simulation by a normal computer is impossible.

The present disclosure has been made in view of such circumstances, and an object thereof is to provide a simulation device, a computer program, and a simulation method, which can solve a minus sign problem while avoiding first-order phase transition.

A simulation device according to an embodiment of the present disclosure is a simulation device, which expresses a Hamiltonian of a system composed of a plurality of spins that can take two values with an initial Hamiltonian and a target Hamiltonian, sets the initial Hamiltonian to a large value in an initial state, and makes the initial Hamiltonian smaller than the target Hamiltonian with time variation so as to simulate a physical quantity of the system in an equilibrium state, the simulation device comprising: a magnetization computation unit configured to compute the average of the sum of predetermined direction components of the plurality of spins as magnetization of the predetermined direction; an initial Hamiltonian computation unit configured to compute a magnetic field function, which includes a first order term and a second or higher order term of the magnetization computed by the magnetization computation unit, as the initial Hamiltonian; a first probability distribution function computation unit configured to compute a probability distribution function for the initial Hamiltonian using an exponential function operator including a term of multiplication of the magnetic field function and a delta function including a variable of a difference between the magnetization computed by the magnetization computation unit and the average of the sum of predetermined direction components of the spins; a spin variable update unit configured to update respective spin variables for the plurality of spins on the basis of probability distribution obtained by computation by the first probability distribution function computation unit; a determination unit configured to determine whether the system has been put into an equilibrium state or not on the basis of the spin variables updated by the spin variable update unit; a first magnetization calculation unit configured to calculate magnetization of the predetermined direction in the equilibrium state if the determination unit determines that the system has been put into an equilibrium state; a magnetic field calculation unit configured to calculate a magnetic field of the predetermined direction for the plurality of spins on the basis of the magnetization calculated by the first magnetization calculation unit and the magnetic field function; a magnetic field determination unit configured to determine whether the magnetic field calculated by the magnetic field calculation unit is in a steady state or not; and a physical quantity calculation unit configured to calculate a physical quantity related to the system if the magnetic field determination unit determines that the magnetic field is in a steady state.

A simulation device according to an embodiment of the present disclosure further comprising a second probability distribution function computation unit configured to carry out integral representation of the delta function included in the probability distribution function computed by the first probability distribution function computation unit and compute a probability distribution function for a Hamiltonian of the system using an exponential function operator including a derived function of the magnetic field function, wherein the spin variable update unit updates a spin variable on the basis of probability distribution for a Hamiltonian of the system obtained by computation by the second probability distribution function computation unit.

A simulation device according to an embodiment of the present disclosure wherein the spin variable update unit updates a spin variable on the basis of probability distribution for a Hamiltonian of the system obtained by updating a derived function of the magnetic field function included in a probability distribution function for a Hamiltonian of the system on the basis of the magnetization calculated by the first magnetization calculation unit if the magnetic field determination unit determines that the magnetic field is not in a steady state.

A simulation device according to an embodiment of the present disclosure further comprising: a setting unit configured to preset a plurality of values of a magnetic field of the predetermined direction; and a second magnetization calculation unit configured to calculate magnetization of the predetermined direction on the basis of the values of a magnetic field set by the setting unit and the inverse function of a derived function of the magnetic field function, wherein the spin variable update unit updates a spin variable on the basis of probability distribution for a Hamiltonian of the system in which a value of a magnetic field set by the setting unit is allocated to a derived function of the magnetic field function included in a probability distribution function for a Hamiltonian of the system, the determination unit determines whether the system has been put into an equilibrium state or not on the basis of the spin variables updated by the spin variable update unit, the first magnetization calculation unit calculates magnetization of the predetermined direction in the equilibrium state if the determination unit determines that the system has been put into an equilibrium state, and the physical quantity calculation unit calculates a physical quantity related to the system if magnetization calculated by the first magnetization calculation unit and the magnetization calculated by the second magnetization calculation unit are equal.

A computer readable non-transitory recording medium recording a computer program according to an embodiment of the present disclosure is a computer program capable of causing a computer to express a Hamiltonian of a system composed of a plurality of spins that can take two values with an initial Hamiltonian and a target Hamiltonian, set the initial Hamiltonian to a large value in an initial state, and make the initial Hamiltonian smaller than the target Hamiltonian with time variation so as to simulate a physical quantity of the system in an equilibrium state, the computer program causing a computer to execute: a step of computing the average of the sum of predetermined direction components of the plurality of spins as magnetization of the predetermined direction; a step of computing a magnetic field function, which includes a first order term and a second or higher order term of the computed magnetization, as the initial Hamiltonian; a step of computing a probability distribution function for the initial Hamiltonian using an exponential function operator including a term of multiplication of the magnetic field function and a delta function including a variable of a difference between the computed magnetization and the average of the sum of predetermined direction components of the spins; a step of updating respective spin variables for the plurality of spins on the basis of probability distribution obtained by computation; a step of determining whether the system has been put into an equilibrium state or not on the basis of the updated spin variables; a step of calculating magnetization of the predetermined direction in the equilibrium state if it is determined that the system has been put into an equilibrium state; a step of calculating a magnetic field of the predetermined direction for the plurality of spins on the basis of the calculated magnetization and the magnetic field function; a step of determining whether the calculated magnetic field is in a steady state or not; and a step of calculating a physical quantity related to the system if it is determined that the magnetic field is in a steady state.

A simulation method according to an embodiment of the present disclosure is a simulation method of expressing a Hamiltonian of a system composed of a plurality of spins that can take two values with an initial Hamiltonian and a target Hamiltonian, setting the initial Hamiltonian to a large value in an initial state, and making the initial Hamiltonian smaller than the target Hamiltonian with time variation so as to simulate a physical quantity of the system in an equilibrium state, the simulation method comprising: a step of computing the average of the sum of predetermined direction components of the plurality of spins as magnetization of the predetermined direction; a step of computing a magnetic field function, which includes a first order term and a second or higher order term of the computed magnetization, as the initial Hamiltonian; a step of computing a probability distribution function for the initial Hamiltonian using an exponential function operator including a term of multiplication of the magnetic field function and a delta function including a variable of a difference between the computed magnetization and the average of the sum of predetermined direction components of the spins; a step of updating respective spin variables for the plurality of spins on the basis of probability distribution obtained by computation; a step of determining whether the system has been put into an equilibrium state or not on the basis of the updated spin variables; a step of calculating magnetization of the predetermined direction in the equilibrium state if it is determined that the system has been put into an equilibrium state; a step of calculating a magnetic field of the predetermined direction for the plurality of spins on the basis of the calculated magnetization and the magnetic field function; a step of determining whether the calculated magnetic field is in a steady state or not; and a step of calculating a physical quantity related to the system if it is determined that the magnetic field is in a steady state.

It is possible with the present disclosure to solve a minus sign problem while avoiding first-order phase transition.

The above and further objects and features of the invention will more fully be apparent from the following detailed description with accompanying drawings.

### BRIEF DESCRIPTION OF THE DRAWINGS

FIG. 1 An explanatory view illustrating an example of configuration of a simulation device according to this embodiment.

FIG. 2 A schematic view illustrating an example of Suzuki-Trotter decomposition.

FIG. 3 A schematic view illustrating an example of a manner of updating a spin variable.

FIG. 4 An explanatory view illustrating an example of the relation between transverse magnetization mx and a transverse field m(tilde)x.

FIG. 5 A flowchart illustrating an example of process procedures of an adaptive quantum Monte Carlo method to be executed by a simulation device according to this embodiment.

FIG. 6 An explanatory view illustrating First Example of a result of simulation by an adaptive quantum Monte Carlo method according to this embodiment.

FIG. 7 An explanatory view illustrating Second Example of a result of simulation by an adaptive quantum Monte Carlo method according to this embodiment.

FIG. 8 An explanatory view illustrating Third Example of a result of simulation by an adaptive quantum Monte Carlo method according to this embodiment.

FIG. 9 A flowchart illustrating an example of process procedures of a quantum Monte Carlo method by data analysis to be carried out by a simulation device according to this embodiment.

FIG. 10 An explanatory view illustrating the concept of a quantum Monte Carlo method by data analysis according to this implementation.

FIG. 11 An explanatory view illustrating First Example of a result of simulation by a quantum Monte Carlo method by data analysis according to this embodiment.

FIG. 12 An explanatory view illustrating Second Example of a result of simulation by a quantum Monte Carlo method by data analysis according to this embodiment.

FIG. 13 An explanatory view illustrating Third Example of a result of simulation by a quantum Monte Carlo method by data analysis according to this embodiment.

FIG. 14 An explanatory view illustrating another example of configuration of a simulation device according to this embodiment.

FIG. 15 A schematic view illustrating an example of an energy gap of a quantum system.

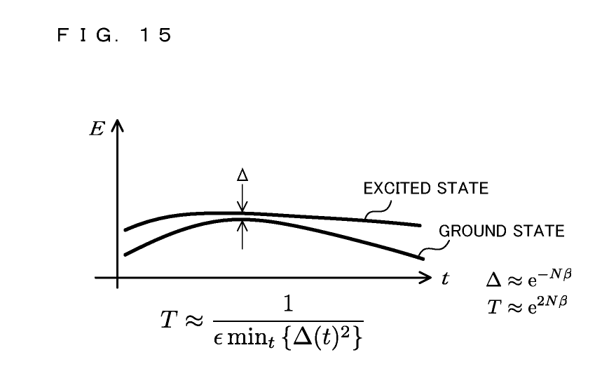

FIG. 16 A schematic view illustrating an example of a phase diagram.

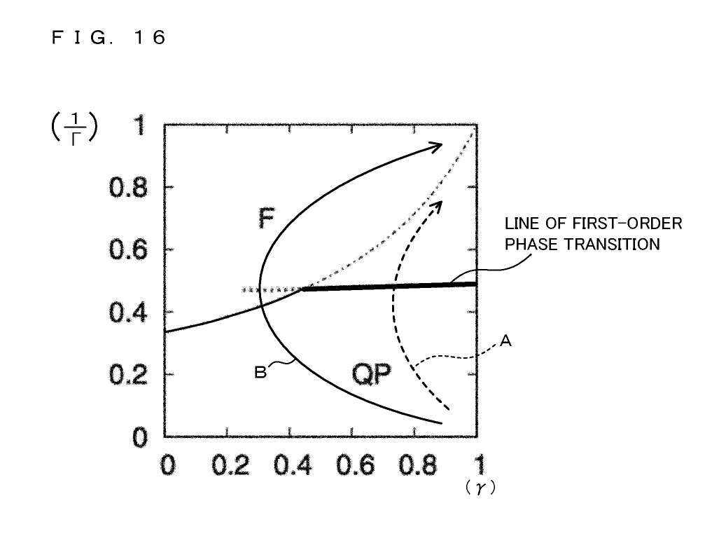

### DESCRIPTION OF EMBODIMENTS

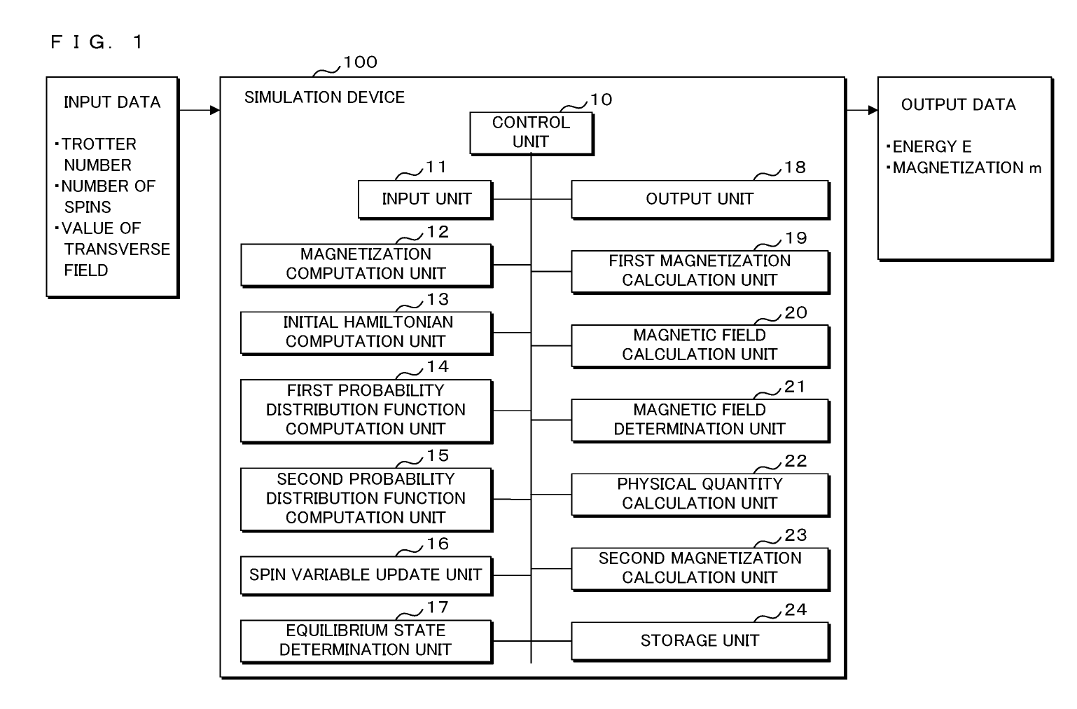

The following description will explain this embodiment with reference to the drawings. FIG. 1 is an explanatory view illustrating an example of configuration of a simulation device 100 according to this embodiment. The simulation device 100 according to this embodiment can drastically expand the simulation range in comparison with conventional quantum annealing and can execute simulation for finding an optimal solution using an Ising model.

The simulation device 100 is provided with a control unit 10 configured to control the entire device, an input unit 11, a magnetization computation unit 12, an initial Hamiltonian computation unit 13, a first probability distribution function computation unit 14, a second probability distribution function computation unit 15, a spin variable update unit 16, an equilibrium state determination unit 17, an output unit 18, a first magnetization calculation unit 19, a magnetic field calculation unit 20, a magnetic field determination unit 21, a physical quantity calculation unit 22, a second magnetization calculation unit 23, a storage unit 24, and the like.

The input unit 11 accepts input data (e.g., Trotter number, the number of spins, a value of a transverse field, and the like) for executing simulation.

The output unit 18 outputs output data (e.g., energy E, magnetization m, and the like), which is the result of simulation.

The magnetization computation unit 12 computes the average of the sum of predetermined direction components of a plurality of spins as magnetization of a predetermined direction. When utilizing a transverse field of the x direction as quantum-mechanical fluctuation in which a spin oriented in the z direction is inverted, the predetermined direction can be the x direction, which is a transverse direction, and magnetization of the predetermined direction can be magnetization mx in the transverse direction. The following description will explain a case where the predetermined direction is a transverse direction. The magnetization computation unit 12 computes transverse magnetization mx as the average of sigma of x-direction components ox of spins.

The simulation device 100 according to this embodiment formulates what is obtained by multiplying a function f, which includes a variable of the average of sigma of x-direction components ox of spins, with the number of spins N as an initial Hamiltonian as expressed at the second term in the right side of Expression (3). The initial Hamiltonian functions as quantum-mechanical fluctuation in which a spin oriented in the z direction is inverted.

$$\begin{matrix}H ( σ ) = {H}_{0} ( σ ) - Nf ( \frac{1}{N} {\sum }_{i = 1}^{N} {σ}_{i}^{x} ) & ( 3 ) \\ f ( {m}_{x} ) = Γ {m}_{x} - γ {m}_{x}^{2} / 2 & ( 4 )\end{matrix}$$

In particular, the initial Hamiltonian computation unit 13 computes a magnetic field function, which includes a first order term and a second or higher order term of transverse magnetization mx, as an initial Hamiltonian. When expressing a magnetic field function as f(mx), the magnetic field function f(mx) can be expressed as f(mx)=Γ·mx+(γ/2)·(mx)², for example, as expressed in Expression (4). Here, coefficient Γ is a parameter for controlling the intensity of quantum fluctuation, and γ is a predetermined coefficient. The initial Hamiltonian can be expressed with a magnetic field function. By including a term of the square of transverse magnetization mx in a magnetic field function, it becomes possible to avoid the problem of first-order phase transition. It is to be noted that a magnetic field function is not limited to Expression (4). It is also to be noted that the above-mentioned “a second or higher order term” means a case including to only a second order term, a case including a higher order term equal to or higher than a third order term in addition to a second order term, or a case not including a second order term but including a higher order term equal to or higher than a third order term.

In Expression (3), a Hamiltonian H0, which is the first term in the right side, expresses a cost function of an optimization problem, and H0 is selected in a manner such that the ground state of the Hamiltonian H0 becomes an optimal solution. Symbol σ denotes a spin variable, which can take values of ±+1. In an initial state (time t=0), coefficient Γ is set to an extremely large value, is decreased with the lapse of time, and eventually becomes 0. First, state investigation is carried out by realizing superposition of a number of states by large quantum fluctuation. As Γ gradually decreases while continuously tracing a momentary ground state at each time point, the relative weight of the Hamiltonian H0 becomes larger than the initial Hamiltonian, and the state eventually reaches the ground state of the Hamiltonian H0. In such a state, a solution for the optimization problem is obtained, and a required physical quantity can be calculated.

The first probability distribution function computation unit 14 computes a probability distribution function for an initial Hamiltonian using an exponential function operator including a term of multiplication of a magnetic field function and a delta function including a variable of a difference between the transverse magnetization mx and the average of the sum of the transverse direction components σx of spins. In particular, a probability distribution function to be computed by the first probability distribution function computation unit 14 can be expressed as in Expression (5).

$$\int {dm}_{x} exp ( N \frac{β}{τ} f ( {m}_{x} ) ) δ ( {Nm}_{x} - {\sum }_{i = 1}^{N} {σ}_{i}^{x} ) \qquad ( 5 )$$

Expression (5) expresses probability distribution obtained after Suzuki-Trotter decomposition. In Expression (5), β is a coefficient proportional to the inverse number of the absolute temperature, and τ denotes a Trotter number. As expressed in Expression (5), arbitrary quantum fluctuation (a problem of an initial Hamiltonian expressed at the second term in the right side of Expression (3)) including f(mx) can be changed into a simple expression having a transverse field by rewriting an effect related to a magnetic field function f(mx).

By introducing a delta function including a variable of a difference between the transverse magnetization mx and the average of the sum of the x-direction components σx of spins as expressed in Expression (5), the delta function becomes 1, the term of multiplication of the delta function and the magnetic field function f(mx) can be replaced with a magnetic field function f(mx) as a result, a higher order term (including XX interaction) equal to or higher than a second order of the sum of the x-direction components (σx) of spins can be removed from the exponential function operator of the probability distribution function, and therefore the minus sign problem is solved in a case where the transverse magnetization mx is equal to the average of the sum of the x-direction components ax of spins.

Expression (6) expresses a Suzuki-Trotter decomposition formula. In Expression (6), A and B are operators, and L is a Trotter number. It is to be noted that a Trotter number is also denoted by t in this specification.

exp(A+B)=lim_{L→∞}(exp(A/L)exp(B/L))^{L} (6)

A Hamiltonian of a quantum system is generally defined by the sum of local Hamiltonians expressing local interaction between components. Since local Hamiltonians are noncommutative with each other, the size of matrix representation of a Hamiltonian of a quantum system becomes large, and the calculation cost becomes high. Hence, the Suzuki-Trotter decomposition formula expressed in Expression (6) can be used to decompose the exponential function operator into multiplication of exponential operators of local Hamiltonians having small size of matrix representation.

The second probability distribution function computation unit 15 carries out integral representation of the delta function included in the probability distribution function computed by the first probability distribution function computation unit 14, and computes a probability distribution function for a Hamiltonian of the system using an exponential function operator including a derived function of the magnetic field function. In particular, the probability distribution function to be computed by the second probability distribution function computation unit 15 can be expressed as in Expression (7).

$$\begin{matrix}{\prod }_{t = 1}^{τ} {e}^{- \frac{β}{τ} {H}_{0} ( {σ}_{t} )} {e}^{\frac{β}{τ} f ( {m}_{x} )} {e}^{- \frac{β}{τ} {\tilde{m}}_{x} ( {Nm}_{x} - {\sum }_{i = 1}^{N} {σ}_{it}^{x} )} & ( 7 ) \\ {\tilde{m}}_{x} = {f}^{′} ( {m}_{x} ) & ( 8 ) \\ P ( σ \vert {m}_{x} ) = \frac{1}{Z ( {m}_{x} )} {\sum }_{t = 1}^{τ} {e}^{- \frac{β}{τ} {H}_{0} ( {σ}_{t} ) + B {\sum }_{i = 1}^{N} {σ}_{i , t} {σ}_{i , t + 1}} & ( 9 ) \\ B = - log tanh ( β {f}^{′} ( {m}_{x} ) ) / 2 & ( 10 )\end{matrix}$$

In Expression (7), τ is a Trotter number, and m(tilde)x can be expressed with a derived function f(mx) related to mx of the magnetic field function f(mx) as in Expression (8). By carrying out integral representation (Fourier integral representation) of the delta function of Expression (5), m(tilde)x is introduced into Expression (7). In Expression (7), a problem of a Hamiltonian having an x-direction component ax of a spin can be treated as a problem of a transverse field, a term related to an x-direction component ax of a spin can be replaced with Trotter interaction having B of Expression (9) as a coefficient by executing Suzuki-Trotter decomposition, and numerical calculation can be executed. This makes it possible to execute simulation using a normal computer. It is to be noted that coefficient B can be expressed in Expression (10). Moreover, Expression (9) is also referred to as a probability distribution function to be computed by the second probability distribution function computation unit 15 in this specification. In Expression (9), Z(mx) is a coefficient to be used for normalization.

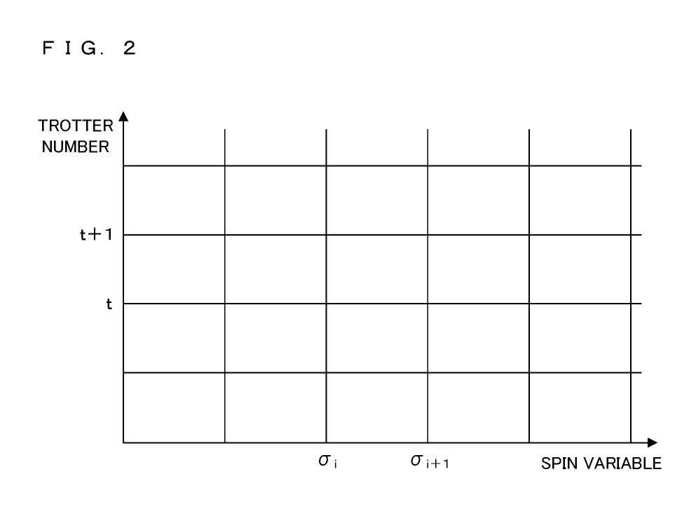

FIG. 2 is a schematic view illustrating an example of Suzuki-Trotter decomposition. In FIG. 2, the horizontal axis represents a spin variable on a one-dimensional lattice and indicates a so-called real space direction. The vertical axis is a direction (Trotter direction) introduced by Suzuki-Trotter decomposition, and state variables are arranged on a two-dimensional lattice. Thus, it can be considered that Suzuki-Trotter decomposition converts a quantum model into a classical model having a state space with a dimension increased by one.

Focusing on the exponential function part of Expression (7), the maximum value of mx is found. By utilizing a saddle point method which focuses only on the maximum point of mx, Expression (9) can be derived. An expression which expresses the condition (to be the maximum point) of the saddle point becomes Expression (8), and m(tilde)x disappears from Expression (9). Expression (9) expresses how a spin variable a behaves when transverse magnetization mx is decided.

The spin variable update unit 16 updates respective spin variables of a plurality of spins on the basis of probability distribution obtained by computation by the first probability distribution function computation unit 14. More particularly, the spin variable update unit 16 updates a spin variable on the basis of probability distribution for a Hamiltonian of a system obtained by computation by the second probability distribution function computation unit 15. Update of a spin variable is achieved by, for example, selecting a spin variable and updating the spin variable by a method, such as a heat bath method or a Metropolis method, which satisfies detailed balance.

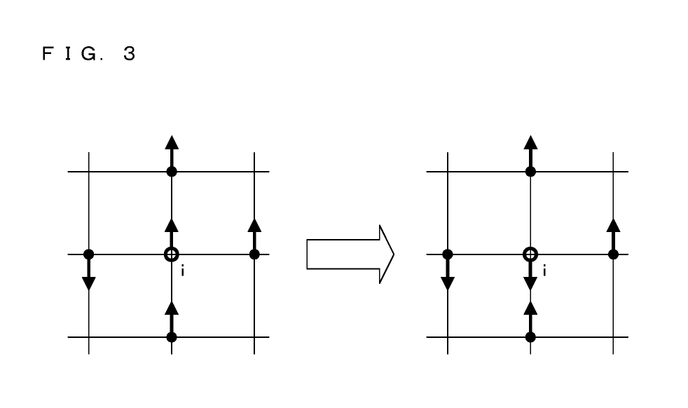

FIG. 3 is a schematic view illustrating an example of a manner of updating a spin variable. The left drawing illustrates a current state of a spin variable, while the right drawing illustrates a case where a spin variable of a lattice i is selected as an arbitrary spin variable. For convenience, it is to be assumed that there are four spin variables around a spin variable of a lattice i, and only the spin variable of the lattice i can be changed (one spin flip).

First, a spin variable in the state illustrated in the left drawing is introduced into Expression (9), so as to calculate current probability distribution Pp. Next, a spin variable in a state where a spin variable of a selected lattice i has been changed is introduced into Expression (9), so as to calculate next new probability distribution Pn as illustrated in the right drawing. A flip probability Pf is calculated from Pf=Pn/Pp. A uniform random number r is generated. In a case where the flip probability Pf is larger than the random number r, the spin variable of the lattice i is set as in the right drawing (the spin is flipped). In a case where the flip probability Pf is not larger than the random number r, the spin variable of the lattice i is set as in the left drawing (the spin is not flipped). The above-described processing is repeated for all lattices (i.e., the number of spins N).

The equilibrium state determination unit 17 has a function as a determination unit and determines whether a system has been put into an equilibrium state or not on the basis of the updated spin variables. Determination of whether the system has been put into an equilibrium state or not is achieved by calculating (measuring) energy E of the system and the magnetization m (moment such as the square or the fourth power of magnetization), for example, and determining that the system has been put into an equilibrium state if there is no fluctuation. Energy E of the system is calculated with Expression (1). The magnetization m can be found by calculating the sum of all spins and dividing the sum by the number of spins.

If the equilibrium state determination unit 17 determines that the system has been put into an equilibrium state, the first magnetization calculation unit 19 calculates transverse magnetization mx in said equilibrium state. The transverse magnetization mx in an equilibrium state can be found from a time average value of the amount calculated with Expression (11). In Expression (11), i denotes the place (lattice point) of a spin, t denotes a Trotter number, τ denotes a Trotter total number, and N denotes a spin total number.

$${m}_{x} = \frac{1}{N τ} {\sum }_{t = 1}^{τ} {\sum }_{i = 1}^{N} {\{ tanh ( \frac{βΓ}{τ} ) \}}^{{σ}_{it} {σ}_{it + 1}} \qquad ( 11 )$$

The magnetic field calculation unit 20 calculates a transverse field for a plurality of spins on the basis of the transverse magnetization mx calculated by the first magnetization calculation unit 19 and the magnetic field function f(mx). The transverse field (m(tilde)x) can be calculated by substituting the transverse magnetization mx into Expression (8) obtained by differentiating the magnetic field function f(mx) by the transverse magnetization mx.

The magnetic field determination unit 21 determines whether the transverse field (m(tilde)x) calculated by the magnetic field calculation unit 20 is in a steady state or not. Whether the transverse field is in a steady state or not can be determined by adaptively changing the value of a transverse field according to the value of transverse magnetization mx in an equilibrium state and determining that the transverse field is in a steady state if the transverse field does not change.

If the magnetic field determination unit 21 determines that the transverse field is in a steady state, the physical quantity calculation unit 22 calculates a physical quantity related to the system. The physical quantity related to the system is energy E or magnetization m, for example. A physical quantity such as the energy E or the magnetization m is repeatedly calculated on the basis of the spin variables while continuing simulation, and the time average of the physical quantity is calculated after the lapse of a certain length of time so as to obtain the result of a physical quantity. Time average enables calculation with an arbitrary accuracy, and the accuracy can be enhanced when the time is lengthened.

The storage unit 24 stores data required for simulation, input data, a processing result obtained during simulation, output data, and the like.

It is possible with the above-described structure to solve the minus sign problem while avoiding first-order phase transition and carry out simulation.

If the magnetic field determination unit 21 determines that the transverse field is not in a steady state, the spin variable update unit 16 updates the derived function f(mx) of the magnetic field function f(mx) included in the probability distribution function for the Hamiltonian of the system on the basis of the transverse magnetization calculated by the first magnetization calculation unit 19 and updates a spin variable on the basis of the updated probability distribution for the Hamiltonian of the system.

In particular, coefficient B in Expression (9) includes a derived function f(mx) of the magnetic field function f(mx) as expressed in Expression (10). That is, when f(mx) is updated with mx, the coefficient B changes, and probability distribution of the system to be computed with Expression (9) also changes as a result.

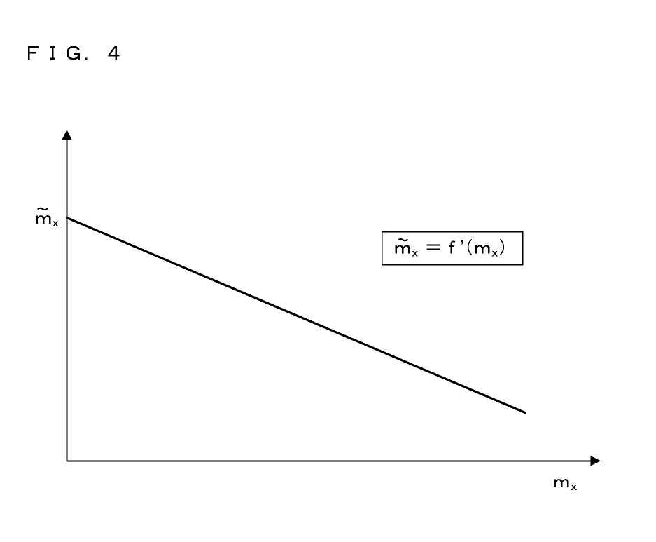

FIG. 4 is an explanatory view illustrating an example of the relation between transverse magnetization mx and a transverse field m(tilde)x. The m(tilde)x is a derived function f(mx) of the magnetic field function f(mx). When the magnetic field function f(mx) is expressed by Expression (4), for example, the derived function f(mx) becomes a linear function of the transverse magnetization mx. That is, the transverse field (m(tilde)x) can be changed by changing the transverse magnetization mx. It is to be noted that the transverse field is constant in conventional quantum annealing.

If the transverse field is not in a steady state, this means that a transverse field or transverse magnetization other than a solution has been obtained as described above. Hence, probability distribution for a Hamiltonian of the system is calculated according to transverse magnetization, and processing of updating a spin variable is carried out again, so that a solution is obtained.

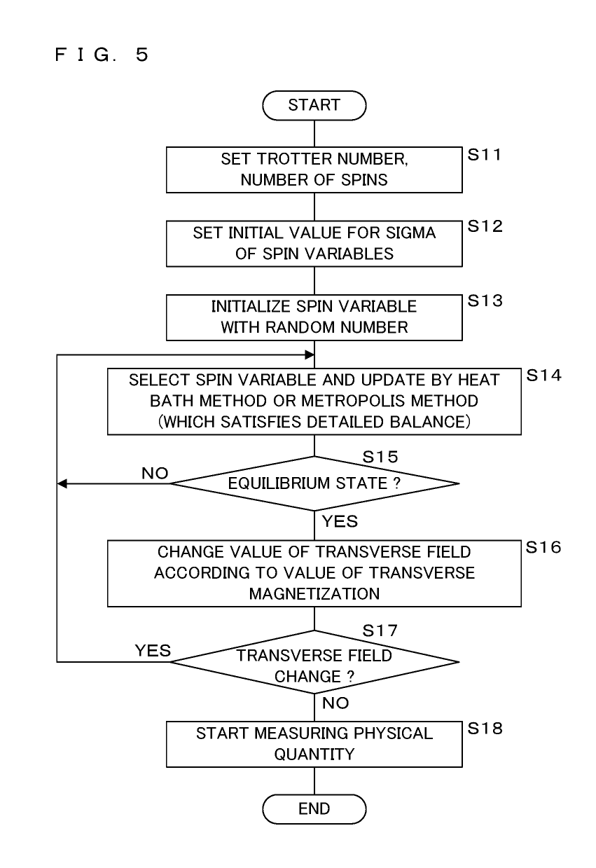

Next, the operation of the simulation device 100 according to this embodiment will be described. FIG. 5 is a flowchart illustrating an example of process procedures of an adaptive quantum Monte Carlo method to be executed by the simulation device 100 according to this embodiment. The term “adaptive” in an adaptive quantum Monte Carlo method is used to distinguish the method from a quantum Monte Carlo method, which is a stochastic method for realizing conventional quantum annealing, and means a simulation method, which can avoid the minus sign problem while avoiding quantum phase transition (first-order phase transition) and can be executed by a normal computer. It is to be noted that the main body of the processing will be described hereinafter as the control unit 10 for convenience.

The control unit 10 sets the Trotter number and the number of spins (S11). Although the Trotter number depends on the performance of the simulator (computer), the Trotter number can be 128, for example. The number of spins N can be an arbitrary size. The calculation accuracy can be enhanced when setting the Trotter number and the number of spins large.

The control unit 10 sets an initial value for sigma of spin variables (S12). When setting an initial value for sigma of spin variables, transverse magnetization mx can be calculated, and therefore the value of a transverse field (m(tilde)x, i.e., f(mx)) can be set to an initial value.

The control unit 10 initializes a spin variable with a random number (S13), selects a spin variable, and carries out updating by a heat bath method or a Metropolis method (a method which satisfies detailed balance) (S14). This allows a Hamiltonian of the system to converge toward the ground state of a target Hamiltonian H0.

The control unit 10 determines whether the system has been put into an equilibrium state or not (S15). Determination of whether the system has been put into an equilibrium state or not is achieved based on whether the value of energy E, the magnetization m, or the like varies or not.

If the system is not in an equilibrium state (NO in S15), the control unit 10 continues the processing from step S14. If the system is in an equilibrium state (YES in S15), the control unit 10 changes the value of a transverse field (m(tilde)x, i.e., F′(mx)) according to the value of the transverse magnetization mx in an equilibrium state (S16).

The control unit 10 determines whether the transverse field changes or not, that is, the transverse field is in a steady state or not (S17). If the transverse field changes (YES in S17), the control unit 10 determines that a transverse field or transverse magnetization other than a solution has been obtained, and continues the processing from step S14.

If the transverse field does not change (NO in S17), the control unit 10 determines that a solution has been obtained, starts measuring (calculating) the physical quantity (S18), finds the time average of measured quantity so as to obtain the result of the physical quantity after the lapse of required time, and terminates the processing.

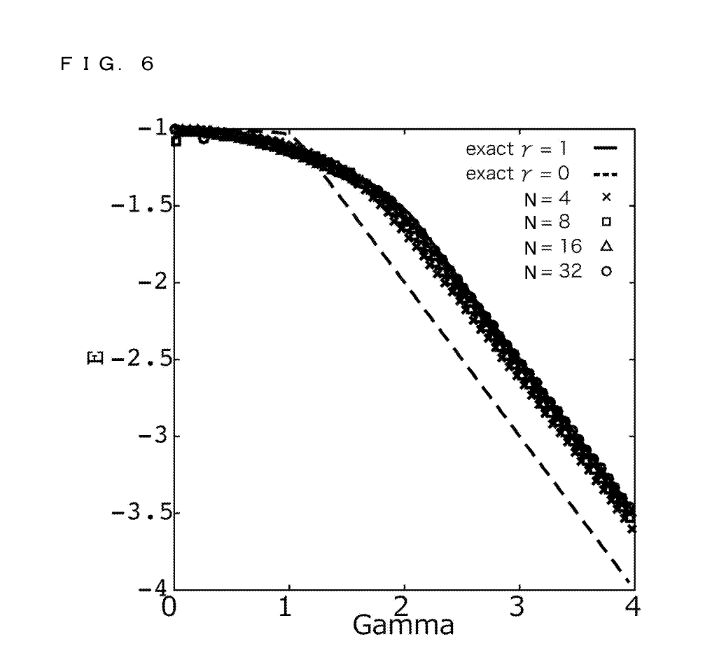

FIG. 6 is an explanatory view illustrating First Example of a result of simulation by an adaptive quantum Monte Carlo method according to this embodiment. In FIG. 6, the horizontal axis represents a transverse field Γ (Gamma), while the vertical axis represents energy E. Symbol N in the figure denotes the number of spins in simulation, and the solid line expressed as exact γ=1 indicates a true solution (correct solution) found by hand calculation. As seen from FIG. 6, the simulation result substantially coincides with the true solution and comes closer to the true solution especially by increasing the number of spins N.

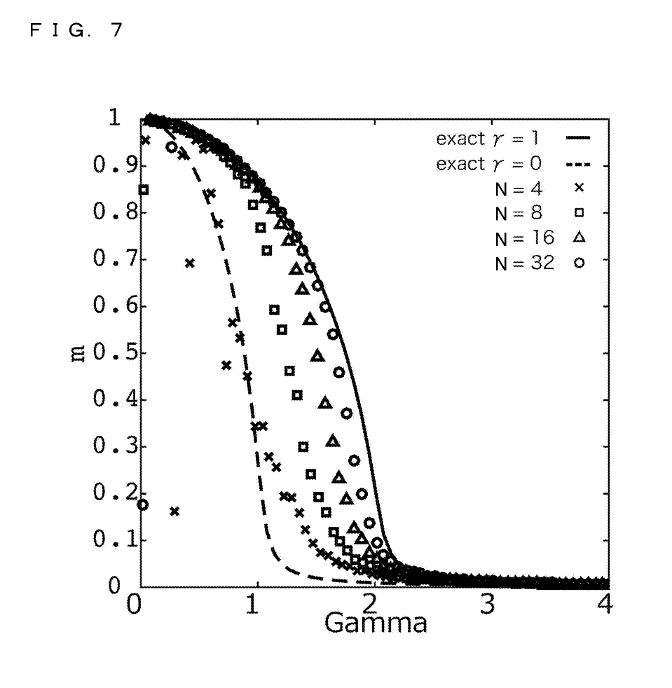

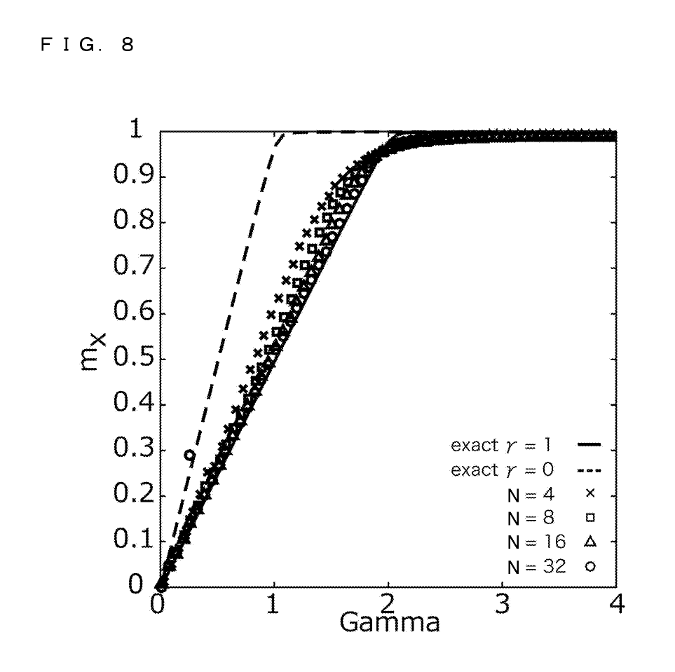

FIG. 7 is an explanatory view illustrating Second Example of a result of simulation by an adaptive quantum Monte Carlo method according to this embodiment, and FIG. 8 is an explanatory view illustrating Third Example of a result of simulation by an adaptive quantum Monte Carlo method according to this embodiment. In FIG. 7, the vertical axis represents magnetization m. In FIG. 8, the vertical axis represents transverse magnetization mx. Both of FIGS. 7 and 8 also show that the simulation result comes closer to the true solution by increasing the number of spins N.

Next, a quantum Monte Carlo method by data analysis to be executed by the simulation device 100 according to this embodiment will be described. A quantum Monte Carlo method by data analysis is a normal quantum Monte Carlo method.

The control unit 10 has a function as a setting unit and presets a plurality of values of a transverse field. That is, a plurality of values of a transverse field are prepared.

The second magnetization calculation unit 23 calculates transverse magnetization on the basis of the inverse function of a derived function of a magnetic field function and a value of a transverse field. Assuming a transverse field m(tilde)x=f(mx), for example, the transverse magnetization mx can be calculated by the inverse function of mx=f(m(tilde)x). By calculating transverse magnetization for a plurality of transverse fields, it is possible to plot the relation between a transverse field and transverse magnetization.

The spin variable update unit 16 updates a spin variable on the basis of probability distribution for a Hamiltonian of a system in which a value of a transverse field set by the control unit 10 is allocated to a derived function of a magnetic field function included in a probability distribution function for a Hamiltonian of the system.

The equilibrium state determination unit 17 determines whether the system has been put into an equilibrium state or not on the basis of the spin variable updated by the spin variable update unit 16.

When the system is put into an equilibrium state, the first magnetization calculation unit 19 calculates transverse magnetization in said equilibrium state. That is, the first magnetization calculation unit 19 calculates transverse magnetization by executing a quantum Monte Carlo method using a preliminarily prepared transverse field. This makes it possible to plot the relation between the transverse field and the transverse magnetization.

If the transverse magnetization calculated by the first magnetization calculation unit 19 and the transverse magnetization calculated by the second magnetization calculation unit 23 are equal, the physical quantity calculation unit 22 calculates a physical quantity related to the system. That is, if the transverse magnetization calculated on the basis of the inverse function of a derived function of a magnetic field function and the transverse magnetization calculated by executing a quantum Monte Carlo method are equal, said transverse magnetization and a corresponding transverse field are found, so that a solution is also found by a data-analytic approach.

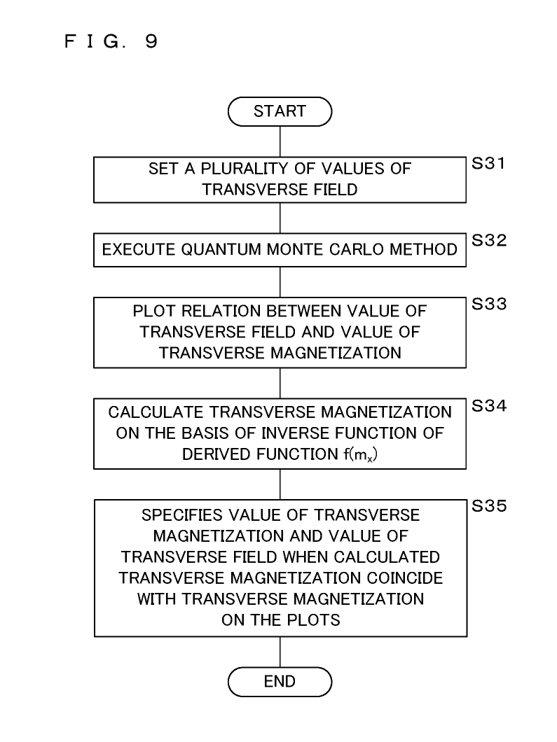

FIG. 9 is a flowchart illustrating an example of process procedures of a quantum Monte Carlo method by data analysis to be carried out by the simulation device 100 according to this embodiment. The control unit 10 sets a plurality of values of a transverse field (m(tilde)x, i.e., f(mx)) (S31) and executes a quantum Monte Carlo method using the respective set values of a transverse field (S32).

The control unit 10 plots the relation between a value of a transverse field and a value of transverse magnetization in association with a value of transverse magnetization obtained by executing a quantum Monte Carlo method and a transverse field of when said transverse magnetization is obtained (S33). Here, it is to be noted that to plot does not necessarily mean drawing actually in a chart but may have any manner that shows association.

The control unit 10 calculates transverse magnetization on the basis of the inverse function of a derived function f(mx) of a magnetic field function f(mx) (S34). In particular, transverse magnetization can be calculated by substituting the respective set values of a transverse field into the inverse function.

The control unit 10 specifies a value of transverse magnetization and a value of a transverse field of when the transverse magnetization calculated by the inverse function coincides with transverse magnetization on the plots (S35). This makes it possible to obtain a true solution, and a result of a physical quantity is obtained as with an adaptive quantum Monte Carlo method. The control unit 10 terminates the processing.

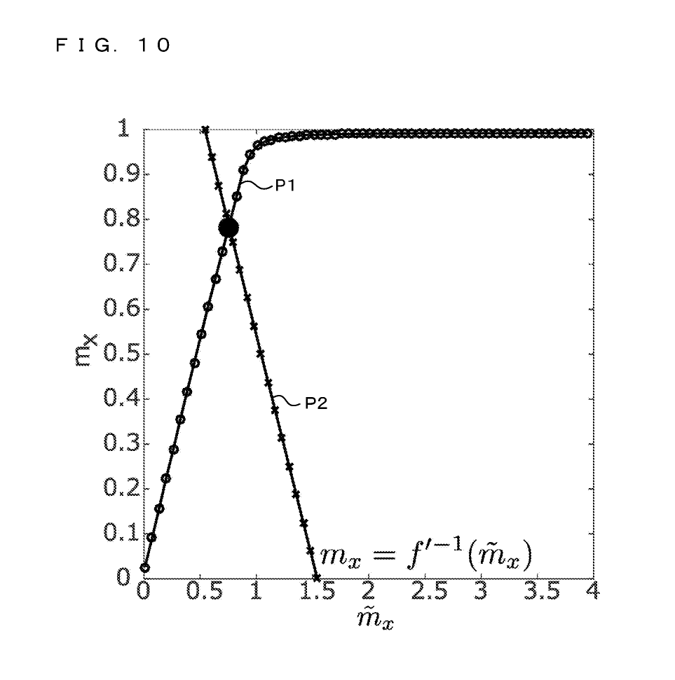

FIG. 10 is an explanatory view illustrating the concept of a quantum Monte Carlo method by data analysis according to this embodiment. In FIG. 10, the horizontal axis represents a value of a transverse field (m(tilde)x), while the vertical axis represents a value of transverse magnetization mx. In FIG. 10, the curve denoted by symbol P1 is obtained by plotting results obtained by a quantum Monte Carlo method. Assuming a transverse field m(tilde)x=f(mx), transverse magnetization mx can be calculated by the inverse function of mx=f(m(tilde)x). The straight line denoted by symbol P2 satisfies the inverse function of mx=f(m(tilde)x). The value of transverse magnetization mx and the value of a transverse field m(tilde)x at a point where the curve P1 and the straight line P2 cross each other becomes a solution.

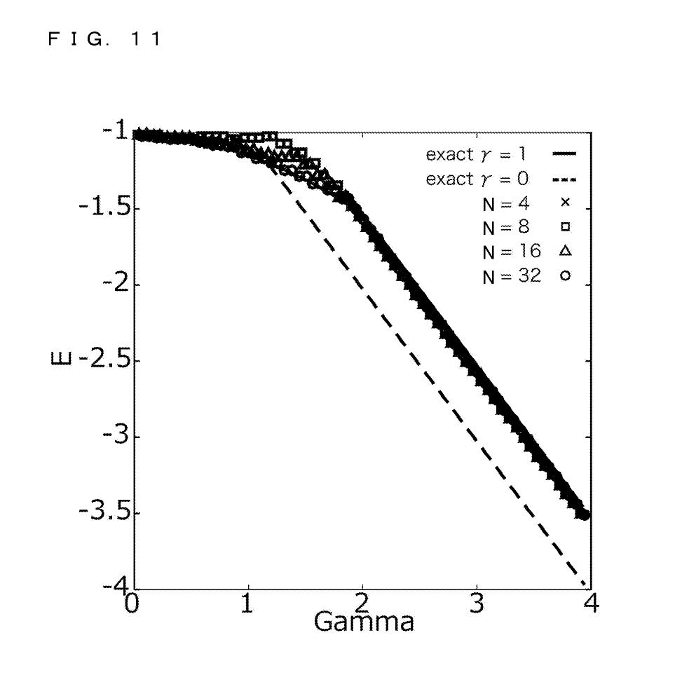

FIG. 11 is an explanatory view illustrating First Example of a result of simulation by a quantum Monte Carlo method by data analysis according to this embodiment. In FIG. 11, the horizontal axis represents a transverse field Γ (Gamma), while the vertical axis represents energy E. Symbol N in the figure denotes the number of spins in simulation, and a chart corresponding to each N is a set of points where the curve P1 and the straight line P2 cross each other. The solid line expressed as exact γ=1 indicates a true solution (correct solution) found by hand calculation. As seen from FIG. 11, the simulation result substantially coincides with the true solution and comes closer to the true solution especially by increasing the number of spins N.

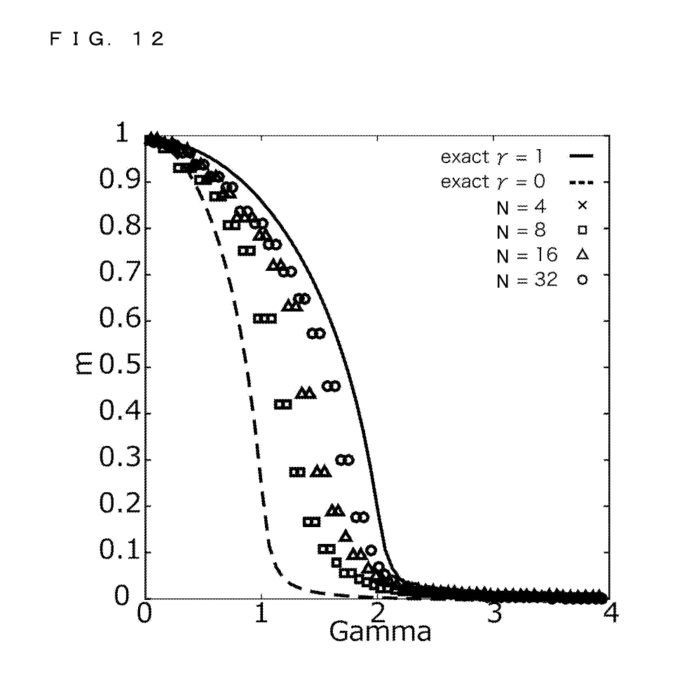

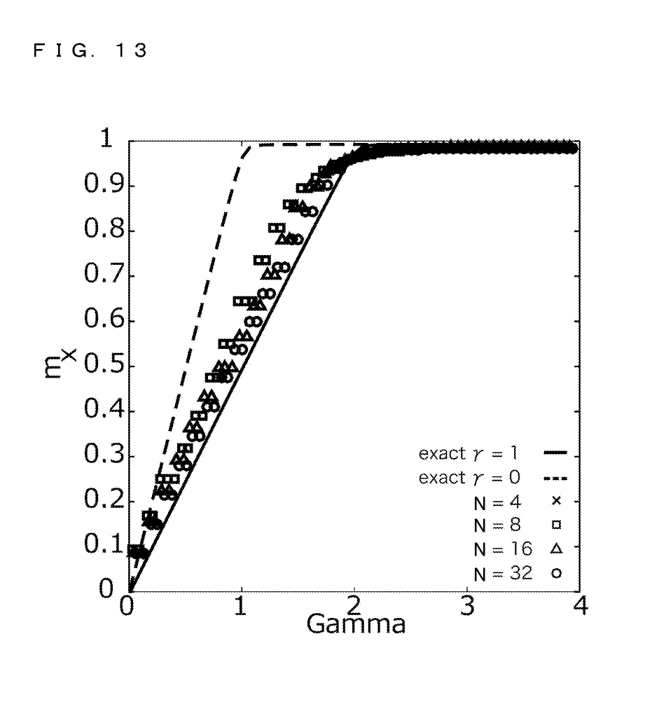

FIG. 12 is an explanatory view illustrating Second Example of a result of simulation by a quantum Monte Carlo method by data analysis according to this embodiment, and FIG. 13 is an explanatory view illustrating Third Example of a result of simulation by a quantum Monte Carlo method by data analysis according to this embodiment. In FIG. 12, the vertical axis represents magnetization m. In FIG. 13, the vertical axis represents transverse magnetization mx. Both of FIGS. 12 and 13 also show that the simulation result comes closer to the true solution by increasing the number of spins N.

The simulation device 100 according to this embodiment can be realized using a computer provided with a CPU (processor), a RAM (memory), and the like. That is, the simulation device 1100 can be realized by loading a computer program, which specifies the respective process procedures as illustrated in FIGS. 5 and 9, to a RAM (memory) provided in the computer and executing the computer program in a CPU (processor).

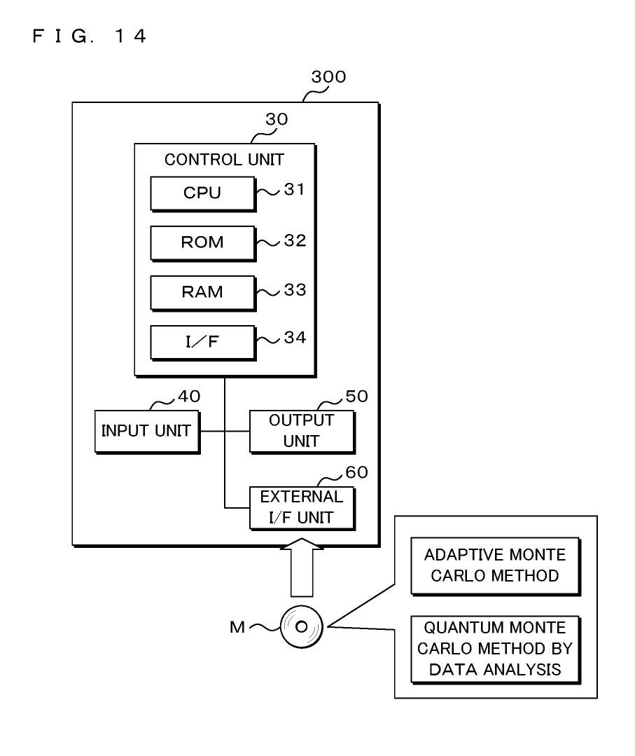

FIG. 14 is an explanatory view illustrating another example of configuration of a simulation device according to this embodiment. Denoted at 300 in FIG. 14 is a normal computer. The computer 300 is provided with a control unit 30, an input unit 40, an output unit 50, an external I/F (interface) unit 60, and the like. The control unit 30 is provided with a CPU 31, a ROM 32, a RAM 33, an I/F (interface) 34, and the like.

The input unit 40 acquires input data for simulation. The output unit 50 outputs output data, which is the result of simulation. The I/F 34 has an interface function between the control unit 30 and each of the input unit 40, the output unit 50, and the external I/F unit 60.

The external I/F unit 60 can read a computer program from a recording medium M (e.g., a medium such as DVD) having a computer program recorded thereon.

Although not illustrated, a computer program recorded on the recording medium M is not limited to a computer program recorded on a freely portable medium, but may include a computer program to be transmitted through the Internet or another communication line. The computer also includes one computer having a plurality of processors mounted thereon, or a computer system composed of a plurality of computers connected with each other via a communication network.

As described above, it is possible with this embodiment to avoid a problem of quantum phase transition, which makes calculation time of simulation as long as an optimal solution cannot be obtained. Since it is possible with this embodiment to avoid a minus sign problem in which probability density becomes minus, simulation can be executed by a normal computer not only for a limited model but for a wide variety of models, application range of a quantum Monte Carlo method can be expanded, and the range of simulation of design or material searching can be expanded. Moreover, a simulation method according to this embodiment can be utilized in a technical field, such as artificial intelligence, machine learning, and a production site of a quantum computer, which requires large-scale calculation.

A simulation device according to this embodiment is a simulation device, which expresses a Hamiltonian of a system composed of a plurality of spins that can take two values with an initial Hamiltonian and a target Hamiltonian, sets the initial Hamiltonian to a large value in an initial state, and makes the initial Hamiltonian smaller than the target Hamiltonian with time variation so as to simulate a physical quantity of the system in an equilibrium state, the simulation device comprising: a magnetization computation unit configured to compute the average of the sum of predetermined direction components of the plurality of spins as magnetization of the predetermined direction; an initial Hamiltonian computation unit configured to compute a magnetic field function, which includes a first order term and a second or higher order term of the magnetization computed by the magnetization computation unit, as the initial Hamiltonian; a first probability distribution function computation unit configured to compute a probability distribution function for the initial Hamiltonian using an exponential function operator including a term of multiplication of the magnetic field function and a delta function including a variable of a difference between the magnetization computed by the magnetization computation unit and the average of the sum of predetermined direction components of the spins; a spin variable update unit configured to update respective spin variables for the plurality of spins on the basis of the probability distribution obtained by computation by the first probability distribution function computation unit; a determination unit configured to determine whether the system has been put into an equilibrium state or not on the basis of the spin variables updated by the spin variable update unit; a first magnetization calculation unit configured to calculate magnetization of the predetermined direction in the equilibrium state if the determination unit determines that the system has been put into an equilibrium state; a magnetic field calculation unit configured to calculate a magnetic field of the predetermined direction for the plurality of spins on the basis of the magnetization calculated by the first magnetization calculation unit and the magnetic field function; a magnetic field determination unit configured to determine whether the magnetic field calculated by the magnetic field calculation unit is in a steady state or not; and a physical quantity calculation unit configured to calculate a physical quantity related to the system if the magnetic field determination unit determines that the magnetic field is in a steady state.

A computer program according to this embodiment is a computer program capable of causing a computer to express a Hamiltonian of a system composed of a plurality of spins that can take two values with an initial Hamiltonian and a target Hamiltonian, set the initial Hamiltonian to a large value in an initial state, and make the initial Hamiltonian smaller than the target Hamiltonian with time variation so as to simulate a physical quantity of the system in an equilibrium state, the computer program causing a computer to execute: a step of computing the average of the sum of predetermined direction components of the plurality of spins as magnetization of the predetermined direction; a step of computing a magnetic field function, which includes a first order term and a second or higher order term of the computed magnetization, as the initial Hamiltonian; a step of computing a probability distribution function for the initial Hamiltonian using an exponential function operator including a term of multiplication of the magnetic field function and a delta function including a variable of a difference between the computed magnetization and the average of the sum of predetermined direction components of the spins; a step of updating respective spin variables for the plurality of spins on the basis of probability distribution obtained by computation; a step of determining whether the system has been put into an equilibrium state or not on the basis of the updated spin variables; a step of calculating magnetization of the predetermined direction in the equilibrium state if it is determined that the system has been put into an equilibrium state; a step of calculating a magnetic field of the predetermined direction for the plurality of spins on the basis of the calculated magnetization and the magnetic field function; a step of determining whether the calculated magnetic field is in a steady state or not; and a step of calculating a physical quantity related to the system if it is determined that the magnetic field is in a steady state.

A computer-readable recording medium according to this embodiment having a computer program recorded thereon, the computer program being capable of causing a computer to express a Hamiltonian of a system composed of a plurality of spins that can take two values with an initial Hamiltonian and a target Hamiltonian, set the initial Hamiltonian to a large value in an initial state, and make the initial Hamiltonian smaller than the target Hamiltonian with time variation so as to simulate a physical quantity of the system in an equilibrium state, the computer program causing a computer to execute: a step of computing the average of the sum of predetermined direction components of the plurality of spins as magnetization of the predetermined direction; a step of computing a magnetic field function, which includes a first order term and a second or higher order term of the computed magnetization, as the initial Hamiltonian; a step of computing a probability distribution function for the initial Hamiltonian using an exponential function operator including a term of multiplication of the magnetic field function and a delta function including a variable of a difference between the computed magnetization and the average of the sum of predetermined direction components of the spins; a step of updating respective spin variables for the plurality of spins on the basis of probability distribution obtained by computation; a step of determining whether the system has been put into an equilibrium state or not on the basis of the updated spin variables; a step of calculating magnetization of the predetermined direction in the equilibrium state if it is determined that the system has been put into an equilibrium state; a step of calculating a magnetic field of the predetermined direction for the plurality of spins on the basis of the calculated magnetization and the magnetic field function; a step of determining whether the calculated magnetic field is in a steady state or not; and a step of calculating a physical quantity related to the system if it is determined that the magnetic field is in a steady state.

A simulation method according to this embodiment is a simulation method of expressing a Hamiltonian of a system composed of a plurality of spins that can take two values with an initial Hamiltonian and a target Hamiltonian, setting the initial Hamiltonian to a large value in an initial state, and making the initial Hamiltonian smaller than the target Hamiltonian with time variation so as to simulate a physical quantity of the system in an equilibrium state, the simulation method comprising: a step of computing the average of the sum of predetermined direction components of the plurality of spins as magnetization of the predetermined direction; a step of computing a magnetic field function, which includes a first order term and a second or higher order term of the computed magnetization, as the initial Hamiltonian; a step of computing a probability distribution function for the initial Hamiltonian using an exponential function operator including a term of multiplication of the magnetic field function and a delta function including a variable of a difference between the computed magnetization and the average of the sum of predetermined direction components of the spins; a step of updating respective spin variables for the plurality of spins on the basis of probability distribution obtained by computation; a step of determining whether the system has been put into an equilibrium state or not on the basis of the updated spin variables; a step of calculating magnetization of the predetermined direction in the equilibrium state if it is determined that the system has been put into an equilibriums state; a step of calculating a magnetic field of the predetermined direction for the plurality of spins on the basis of the calculated magnetization and the magnetic field function; a step of determining whether the calculated magnetic field is in a steady state or not; and a step of calculating a physical quantity related to the system if it is determined that the magnetic field is in a steady state.

The magnetization computation unit computes the average of the sum of predetermined direction components of a plurality of spins as magnetization of said predetermined direction. When utilizing a transverse field of the x direction as quantum-mechanical fluctuation in which a spin oriented in the z direction is inverted, the predetermined direction can be the x direction, which is a transverse direction, and magnetization of the predetermined direction can be magnetization mx in the transverse direction. That is, the transverse magnetization mx is computed as the average of sigma of x-direction components of spins.

The initial Hamiltonian computation unit computes a magnetic field function including a first order term and a second or higher order term of the computed magnetization as an initial Hamiltonian. When expressing a magnetic field function as f(mx), the magnetic field function f(mx) can be suppressed as f(mx)=Γ·mx+(γ/2)·(mx)², for example. The initial Hamiltonian can be suppressed by a magnetic field function. By including a term of the square of transverse magnetization mx in a magnetic field function, it becomes possible to avoid a problem of first-order phase transition.

The first probability distribution function computation unit computes a probability distribution function for an initial Hamiltonian using an exponential function operator including a term of multiplication of a magnetic field function and a delta function including a variable of a difference between the computed magnetization and the average of the sum of predetermined direction components of spins. By introducing a delta function including a variable of a difference between the magnetization and the average of the sum of predetermined direction components of spins, the delta function becomes 1, the term of multiplication of the delta function and the magnetic field function can be replaced with a magnetic field function as a result, a higher order term equal to or higher than a second order of the sum of predetermined direction components (σx) of spins can be removed from the exponential function operator of the probability distribution function, and therefore the minus sign problem is solved in a case where the transverse magnetization mx is equal to the average of the sum of predetermined direction components of spins.

The spin variable update unit updates respective spin variable of a plurality of spins on the basis of probability distribution obtained by computation. For example, a spin variable is selected and updated by a method, such as a heat bath method or a Metropolis method, which satisfies detailed balance.

The determination unit determines whether the system has been put into an equilibrium state or not on the basis of the updated spin variables. Determination of whether the system has been put into an equilibrium state or not is achieved by calculating (measuring) energy of the system and magnetization (m-ment such as the square or fourth power of magnetization), for example, and determining that the system has been put into an equilibrium state if there is no fluctuation.

When the system is put into an equilibrium state, the first magnetization calculation unit calculates magnetization (transverse magnetization mx) of a predetermined direction in said equilibrium state.

The magnetic field calculation unit calculates a magnetic field (transverse field) of a predetermined direction for a plurality of spins on the basis of the calculated magnetization (transverse magnetization) and the magnetic field function. The transverse field can be calculated by substituting transverse magnetization into an expression obtained by differentiating the magnetic field function by the transverse magnetization.

The magnetic field determination unit determines whether the calculated magnetic field (transverse field) is in a steady state or not. Whether the transverse field is in a steady state or not can be determined by adaptively changing the value of a transverse field according to the value of transverse magnetization in an equilibrium state and determining that the magnetic field is in a steady state if transverse field does not change.

If it is determined that the transverse field is in a steady state, the physical quantity calculation unit calculates a physical quantity related to the system. The physical quantity related to the system is energy or magnetization, for example. A physical quantity such as energy or magnetization is repeatedly calculated on the basis of the spin variables while continuing simulation, and the time average of the physical quantity is calculated after the lapse of a certain length of time so as to obtain the result of a physical quantity.

It is possible with the above-described structure to solve a minus sign problem while avoiding first-order phase transition and carry out simulation.

A simulation device according to this embodiment further comprising a second probability distribution function computation unit configured to carry out integral representation of the delta function included in the probability distribution function computed by the first probability distribution function computation unit and compute a probability distribution function for a Hamiltonian of the system using an exponential function operator including a derived function of the magnetic field function, wherein the spin variable update unit updates a spin variable on the basis of probability distribution for a Hamiltonian of the system obtained by computation by the second probability distribution function computation unit.

The second probability distribution function computation unit carries out integral representation of a delta function included in the probability distribution function computed by the first probability distribution function computation unit, and computes a probability distribution function for a Hamiltonian of the system using an exponential function operator including a derived function of the magnetic field function. By carrying out integral representation of a delta function, a derived function of the magnetic field function can be introduced. By executing Suzuki-Trotter decomposition, a term related to an x-direction component (ox) of a spin can be replaced with Trotter interaction, and it becomes possible to execute numerical calculation.

The spin variable update unit updates a spin variable on the basis of probability distribution for a Hamiltonian of a system obtained by computation by the second probability distribution function computation unit. This makes it possible to execute simulation using a normal computer.

A simulation device according to this embodiment wherein the spin variable update unit updates a spin variable on the basis of probability distribution for a Hamiltonian of the system obtained by updating a derived function of the magnetic field function included in a probability distribution function for a Hamiltonian of the system on the basis of the magnetization calculated by the first magnetization calculation unit if the magnetic field determination unit determines that the magnetic field is not in a steady state.

If it is determined that a transverse field is not in a steady state, the spin variable update unit updates a spin variable on the basis of probability distribution for a Hamiltonian of a system obtained by updating a derived function of a magnetic field function included in a probability distribution function for a Hamiltonian of a system on the basis of the transverse magnetization calculated by the first magnetization calculation unit.

If the transverse field is not in a steady state, this means that a transverse field or transverse magnetization other than a solution has been obtained. Hence, probability distribution for a Hamiltonian of the system is calculated according to transverse magnetization, and processing of updating a spin variable is carried out again, so that a solution is obtained.

A simulation device according to this embodiment further comprising: a setting unit configured to preset a plurality of values of a magnetic field of the predetermined direction; and a second magnetization calculation unit configured to calculate magnetization of the predetermined direction on the basis of the value of a magnetic field set by the setting unit and the inverse function of a derived function of the magnetic field function, wherein the spin variable update unit updates a spin variable on the basis of probability distribution for a Hamiltonian of the system in which a value of a magnetic field set by the setting unit is allocated to a derived function of the magnetic field function included in a probability distribution function for a Hamiltonian of the system, the determination unit determines whether the system has been put into an equilibrium state or not on the basis of the spin variables updated by the spin variable update unit, the first magnetization calculation unit calculates magnetization of the predetermined direction in the equilibrium state if the determination unit determines that the system has been put into an equilibrium state, and the physical quantity calculation unit calculates a physical quantity related to the system if magnetization calculated by the first magnetization calculation unit and the magnetization calculated by the second magnetization calculation unit are equal.

The setting unit presets a plurality of values of a magnetic field (transverse field) of a predetermined direction. That is, a plurality of values of a transverse field are prepared.

The second magnetization calculation unit calculates magnetization (transverse magnetization) of a predetermined direction on the basis of the inverse function of a derived function of a magnetic field function and a value of a transverse field. By calculating transverse magnetization for a plurality of transverse fields, it is possible to plot the relation between a transverse field and transverse magnetization.

The spin variable update unit updates a spin variable on the basis of probability distribution for a Hamiltonian of a system in which a value of a magnetic field set by the setting unit is allocated to a derived function of a magnetic field function included in a probability distribution function for a Hamiltonian of the system. The determination unit determines whether the system has been put into an equilibrium state or not on the basis of the spin variable updated by the spin variable update unit. When the system is put into an equilibrium state, the first magnetization calculation unit calculates transverse magnetization in said equilibrium state. That is, transverse magnetization is calculated by executing a quantum Monte Carlo method using a preliminarily prepared transverse field. This makes it possible to plot the relation between a transverse field and transverse magnetization.

If the magnetization calculated by the first magnetization calculation unit and the magnetization calculated by the second magnetic calculation unit are equal, the physical quantity calculation unit calculates a physical quantity related to the system. That is, if the transverse magnetization calculated on the basis of the inverse function of a derived function of a magnetic field function and the transverse magnetization calculated by executing a quantum Monte Carlo method are equal, said transverse magnetization and a corresponding transverse field are found, so that a solution is also found by a data-analytic approach.

It is to be noted that, as used herein and in the appended claims, the singular forms “a”, “an”, and “the” include plural referents unless the context clearly dictates otherwise.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1-6. (canceled)

7. A simulation device, which expresses a Hamiltonian of a system composed of a plurality of spins that can take two values with an initial Hamiltonian and a target Hamiltonian, sets the initial Hamiltonian to a large value in an initial state, and makes the initial Hamiltonian smaller than the target Hamiltonian with time variation so as to simulate a physical quantity of the system in an equilibrium state, the simulation device comprising:
a magnetization computation unit configured to compute an average of the sum of predetermined direction components of the plurality of spins as magnetization of the predetermined direction;
an initial Hamiltonian computation unit configured to compute a magnetic field function, which includes a first order term and a second or higher order term of the magnetization computed by the magnetization computation unit, as the initial Hamiltonian;
a first probability distribution function computation unit configured to compute a probability distribution function for the initial Hamiltonian using an exponential function operator including a term of multiplication of the magnetic field function and a delta function including a variable of a difference between the magnetization computed by the magnetization computation unit and the average of the sum of predetermined direction components of the spins;
a spin variable update unit configured to update respective spin variables for the plurality of spins on the basis of probability distribution obtained by computation by the first probability distribution function computation unit;
a determination unit configured to determine whether the system has been put into an equilibrium state or not on the basis of the spin variables updated by the spin variable update unit;
a first magnetization calculation unit configured to calculate magnetization of the predetermined direction in the equilibrium state if the determination unit determines that the system has been put into an equilibrium state;
a magnetic field calculation unit configured to calculate a magnetic field of the predetermined direction for the plurality of spins on the basis of the magnetization calculated by the first magnetization calculation unit and the magnetic field function;
a magnetic field determination unit configured to determine whether the magnetic field calculated by the magnetic field calculation unit is in a steady state or not; and
a physical quantity calculation unit configured to calculate a physical quantity related to the system if the magnetic field determination unit determines that the magnetic field is in a steady state.

8. The simulation device according to claim 7, further comprising a second probability distribution function computation unit configured to carry out integral representation of the delta function included in the probability distribution function computed by the first probability distribution function computation unit and compute a probability distribution function for a Hamiltonian of the system using an exponential function operator including a derived function of the magnetic field function,
wherein the spin variable update unit updates a spin variable on the basis of probability distribution for a Hamiltonian of the system obtained by computation by the second probability distribution function computation unit.

9. The simulation device according to claim 8, wherein the spin variable update unit updates a spin variable on the basis of probability distribution for a Hamiltonian of the system obtained by updating a derived function of the magnetic field function included in a probability distribution function for a Hamiltonian of the system on the basis of the magnetization calculated by the first magnetization calculation unit if the magnetic field determination unit determines that the magnetic field is not in a steady state.

10. The simulation device according to claim 9, further comprising:
a setting unit configured to preset a plurality of values of a magnetic field of the predetermined direction; and
a second magnetization calculation unit configured to calculate magnetization of the predetermined direction on the basis of the values of a magnetic field set by the setting unit and an inverse function of a derived function of the magnetic field function,
wherein the spin variable update unit updates a spin variable on the basis of probability distribution for a Hamiltonian of the system in which a value of a magnetic field set by the setting unit is allocated to a derived function of the magnetic field function included in a probability distribution function for a Hamiltonian of the system,
the determination unit determines whether the system has been put into an equilibrium state or not on the basis of the spin variables updated by the spin variable update unit,
the first magnetization calculation unit calculates magnetization of the predetermined direction in the equilibrium state if the determination unit determines that the system has been put into an equilibrium state, and
the physical quantity calculation unit calculates a physical quantity related to the system if magnetization calculated by the first magnetization calculation unit and magnetization calculated by the second magnetization calculation unit are equal.

11. A computer readable non-transitory recording medium recording a computer program capable of causing a computer to express a Hamiltonian of a system composed of a plurality of spins that can take two values with an initial Hamiltonian and a target Hamiltonian, set the initial Hamiltonian to a large value in an initial state, and make the initial Hamiltonian smaller than the target Hamiltonian with time variation so as to simulate a physical quantity of the system in an equilibrium state, the computer program causing a computer to execute:
a step of computing an average of the sum of predetermined direction components of the plurality of spins as magnetization of the predetermined direction;
a step of computing a magnetic field function, which includes a first order term and a second or higher order term of the computed magnetization, as the initial Hamiltonian;
a step of computing a probability distribution function for the initial Hamiltonian using an exponential function operator including a term of multiplication of the magnetic field function and a delta function including a variable of a difference between the computed magnetization and the average of the sum of predetermined direction components of the spins;
a step of updating respective spin variables for the plurality of spins on the basis of probability distribution obtained by computation;
a step of determining whether the system has been put into an equilibrium state or not on the basis of the updated spin variables;
a step of calculating magnetization of the predetermined direction in the equilibrium state if it is determined that the system has been put into an equilibrium state;
a step of calculating a magnetic field of the predetermined direction for the plurality of spins on the basis of the calculated magnetization and the magnetic field function;
a step of determining whether the calculated magnetic field is in a steady state or not; and
a step of calculating a physical quantity related to the system if it is determined that the magnetic field is in a steady state.

12. A simulation method of expressing a Hamiltonian of a system composed of a plurality of spins that can take two values with an initial Hamiltonian and a target Hamiltonian, setting the initial Hamiltonian to a large value in an initial state, and making the initial Hamiltonian smaller than the target Hamiltonian with time variation so as to simulate a physical quantity of the system in an equilibrium state, the simulation method comprising:
a step of computing an average of the sum of predetermined direction components of the plurality of spins as magnetization of the predetermined direction;
a step of computing a magnetic field function, which includes a first order term and a second or higher order term of the computed magnetization, as the initial Hamiltonian;
a step of computing a probability distribution function for the initial Hamiltonian using an exponential function operator including a term of multiplication of the magnetic field function and a delta function including a variable of a difference between the computed magnetization and the average of the sum of predetermined direction components of the spins;
a step of updating respective spin variables for the plurality of spins on the basis of probability distribution obtained by computation;
a step of determining whether the system has been put into an equilibrium state or not on the basis of the updated spin variables;
a step of calculating magnetization of the predetermined direction in the equilibrium state if it is determined that the system has been put into an equilibrium state;
a step of calculating a magnetic field of the predetermined direction for the plurality of spins on the basis of the calculated magnetization and the magnetic field function;
a step of determining whether the calculated magnetic field is in a steady state or not; and
a step of calculating a physical quantity related to the system if it is determined that the magnetic field is in a steady state.
